(19) United States
(12) Patent Application Publication
(10) Pub. No.: US 2026/0206282 A1
(43) Pub. Date: Jul. 16, 2026

(54) TRANSISTOR HAVING AN INDEPENDENTLY CONTROLLED BODY CONTACT REGION WHICH HAS A REDUCED LENGTH TO REDUCE PARASITIC CAPACITANCE

(71) Applicant: QUALCOMM Incorporated, San Diego, CA (US)

(72) Inventors: Yufei Wu, San Diego, CA (US); Hyunchul Jung, San Diego, CA (US); Abhijeet Paul, San Diego, CA (US); Ravi Pramod Kumar Vedula, San Diego, CA (US)

(21) Appl. No.: 19/018,529

(22) Filed: Jan. 13, 2025

(51) Int. Cl. H10D 64/27; H03F 3/195; H03K 17/687; H10D 86/00; H10D 86/01; H10D 86/80

(52) U.S. Cl. CPC H10D 64/529; H03F 3/195; H03K 17/687; H10D 64/518; H10D 86/01; H10D 86/201; H10D 86/80; H03F 2200/294

(57) ABSTRACT

Aspects include a transistor having an independently controlled body contact region which has a reduced length to reduce parasitic capacitance. The transistor includes a body formed from a semiconductor layer. The source and drain regions extend to a source end and to a drain end, respectively. A poly region includes a gate region above the body to generate an electric field in the body and control the flow of current in the body. The gate region has a gate length and a gate width extending from a first gate end to a second gate end. The poly region also includes a poly extension region which extends from the first gate end. The body contact region is below the poly extension region and has a second polarity and is directly adjacent to a third second side of the body. The body contact region has a reduced length approximately equal to the gate length.

### TECHNICAL FIELD

The field of the disclosure relates to field-effect transistors (FETs), and more particularly to FET designs formed as silicon-on-insulator (SOI) substrates.

### BACKGROUND

Transistors are essential components in modern electronic devices, and large numbers of transistors are employed in integrated circuits (ICs) therein. For example, components such as central processing units (CPUs) and memory systems each employ a large quantity of transistors for logic circuits and memory devices. Transistors are also employed in radio-frequency (RF) devices, such as modern smart phones, and other portable devices have extended the use of different wireless links with a variety of technologies in different RF bands.

Field-effect transistors (FETs) can be formed as silicon-on-insulator (SOI) substrate FETs. SOI substrate FETs are formed in thin layers of silicon that are isolated from the main body of the SOI wafer handle substrate by a layer of an electrical insulator, usually silicon dioxide. The silicon layer thickness ranges from several microns (i.e., micrometers (μm)) for electrical power switching devices to less than five hundred (500) Angstroms (Å) for high-performance microprocessors. FETs include gate, drain, source, and body terminals. The body terminal controls the electrical characteristics of the FET by affecting the threshold voltage and channel conductivity. Many discrete FETs internally couple the body terminal with the source terminal. In an N+ metal oxide silicon (NMOS) FET, the body terminal and source terminal are typically connected to ground. In a PMOS FET, the body terminal and source terminal are typically connected to the highest voltage in a circuit in which the PMOS FET is deployed.

During operation of a FET, electron hole pairs are generated in the body. In particular, an inversion region (also known as a conduction channel) is created under the gate terminal which conducts electrons between the drain and source terminals and the paired holes form a depletion region adjacent to the inversion region. This accumulation of holes in the FET increases the internal resistance of the FET which reduces the threshold voltage leading to runaway drain current at high drain voltages (V_{ds}) which appears as a “kink” in the output characteristics of the FET. To alleviate the accumulation of holes, a body contact region abuts the body to help drain the accumulation of holes.

### SUMMARY OF THE DISCLOSURE

Aspects disclosed herein include a transistor having an independently controlled body contact region which has a reduced length to reduce parasitic capacitance, and related methods thereto. The transistor includes a body formed from a semiconductor layer (i.e., silicon). The transistor may be a silicon-on-insulator (SOI) transistor as an example. A source region and a drain region of the transistor are formed on opposite sides of the body in the semiconductor layer by implanting or diffusing doping material of a first polarity in the semiconductor layer. The source and drain regions extend to a source end and to a drain end, respectively. A poly region includes a gate region which is formed in an insulating layer above the body to generate an electric field in the body and control the flow of current in the body. The gate region has a gate length and a gate width extending from a first gate end in line with the first drain end to a second gate end. The poly silicon (“poly”) region also includes a poly extension region which extends from the first gate end outside the perimeter of the source, drain, and gate regions. The body contact region is below the poly extension region and has a second polarity and is directly adjacent to a third side of the body. The body contact region has a reduced length approximately equal to the gate length and is coupled to a body contact independent of the source region.

In this regard, the body contact region which has a reduced length advantageously reduces the parasitic capacitance of the transistor including parasitic capacitance between the body contact region and the source and drain regions. Additionally, the independent control of the body contact region and, thus, the body bias of the transistor advantageously enables flexible tuning of characteristics of the transistor including threshold voltage. When the transistor with the body contact region having a reduced length is deployed in a low-noise amplifier (LNA), the parasitic capacitance is reduced as compared to conventional body-controlled transistors. Furthermore, when the LNA deploys the transistor with the body contact region having a reduced length as the cascode transistor, the independent body control feature can more finely tune the threshold voltage of the transistor to address headroom issues in the cascode transistor. Moreover, the transistor with the body contact region having a reduced length and the independently controlled body reduces off-state current leakage. When the transistor with the body contact region having a reduced length is deployed in a radio frequency (RF) switch, the off-state capacitance of the RF switch is reduced compared to a conventional H-gate configuration and improves the level of functionality and safety of an electrical device as measured against the standards set by the International Electrotechnical Commission (IEC).

In an aspect, an electronic device is provided. The electronic device comprises an insulation layer extending in a first direction and a second direction orthogonal to the first direction and a semiconductor layer extending in the first direction and the second direction, the semiconductor layer adjacent to the insulation layer in a third direction orthogonal to the first direction and the second direction. The semiconductor layer comprises a transistor, comprising a body region, a drain region of a first polarity and adjacent to a first side of the body region in the first direction, the drain region extending in the second direction, and a source region of the first polarity and adjacent to a second side of the body region opposite the first side in the first direction. The transistor further comprises a poly region, comprising a gate region extending in the first direction and the second direction, the gate region adjacent to the body region in the third direction, the body region between the drain region and the source region, the gate region having a gate length extending in the first direction and a gate width extending in the second direction from a first gate end to a second gate end, and a poly extension region extending in the second direction from the first gate end. The transistor further comprises a body contact region having a second polarity and directly adjacent, in the second direction, to a third side of the body region, and under the poly extension region, wherein the body contact region has a body contact region length in the first direction equal to the gate length and a body contact coupled to the body contact region independent of the source region.

In another aspect, a method of fabricating an electronic device to reduce parasitic capacitance. The method comprises fabricating an insulation layer extending in a first direction and a second direction orthogonal to the first direction, and fabricating a semiconductor layer extending in the first direction and the second direction, the semiconductor layer adjacent to the insulation layer in a third direction orthogonal to the first direction and the second direction. Wherein fabricating the semiconductor layer comprises fabricating a body region, fabricating a drain region of a first polarity and adjacent to a first side of the body region in the first direction, the drain region extending in the second direction, and fabricating a source region of the first polarity and adjacent to a second side of the body region opposite the first side in the first direction, the source region extending in the second direction. The method further comprises fabricating a poly region, comprising fabricating a gate region extending in the first direction and the second direction, the gate region adjacent to the body region in the third direction, the body region between the drain region and the source region, the gate region having a gate length extending in the first direction and a gate width extending in the second direction from a first gate end to a second gate end and fabricating a poly extension region extending in the second direction from the first gate end. The method further comprises fabricating a body contact region having a second polarity and directly adjacent, in the second direction, to a third side of the body region, and under the poly extension region, wherein the body contact region has a body contact region length in the first direction equal to the gate length and fabricating a body contact coupled to the body contact region independent of the source region.

In another aspect, an NFET transistor is provided. The NFET transistor comprises a semiconductor layer extending in a first direction and a second direction orthogonal to the first direction, the semiconductor layer comprises a body region, an n-type drain region adjacent to a first side of the body region in the first direction, the n-type drain region extending in the second direction and an n-type source region adjacent to a second side of the body region opposite the first side in the first direction, the n-type source region extending in the second direction. The NFET transistor further comprises a poly region, comprising a gate region extending in the first direction and the second direction, the gate region above the body region, the body region between the n-type drain region and the n-type source region, the gate region having a gate length extending in the first direction and a gate width extending in the second direction from a first gate end to a second gate end and a poly extension region extending in the second direction from the first gate end. The NFET transistor further comprises a p-type body contact region directly adjacent, in the second direction, to a third side of the body region, and under the poly extension region, wherein the p-type body contact region has a body contact region length in the first direction equal to the gate length and a body contact coupled to the p-type body contact region independent of the n-type source region.

### BRIEF DESCRIPTION OF THE FIGURES

FIG. 1 is a top view of an exemplary radio frequency (RF) switch including a transistor having an independently controlled body contact region which has a reduced length to reduce parasitic capacitance;

FIG. 2A is a top view of an exemplary low-noise amplifier (LNA) including two transistors having an independently controlled body contact region which has a reduced length to reduce parasitic capacitance;

FIG. 2B is a schematic of the LNA in FIG. 2A;

FIG. 3A is a top view of an exemplary n-type field-effect transistor (FET) (NFET) having an independently controlled body contact region which has a reduced length to reduce parasitic capacitance;

FIG. 3B is a side view of the NFET at cut line A1-A1′ in FIG. 3A;

FIG. 3C is a side view of the NFET at cut line A2-A2′ in FIG. 3A;

FIG. 3D is a side view of the NFET at cut line A3-A3′ in FIG. 3A;

FIG. 3E is a side view of the NFET at cut line B-B′ in FIG. 3A;

FIG. 4 is a top view of an exemplary NFET having an independently controlled body contact region which has a reduced length to reduce parasitic capacitance wherein the gate width of the transistor is greater than or equal to four micrometers (4 μm).

FIG. 5 is a top view of an exemplary p-type FET (PFET) having an independently controlled body contact region which has a reduced length to reduce parasitic capacitance;

FIG. 6A is a top view of an exemplary NFET having an independently controlled body contact region which has a reduced length to reduce parasitic capacitance;

FIG. 6B is a side view of the NFET at cut line C1-C1′ in FIG. 6A;

FIG. 6C is a side view of the NFET at cut line C2-C2′ in FIG. 6A;

FIG. 6D is a side view of the NFET at cut line D1-D1′ in FIG. 6A;

FIG. 6E is a side view of the NFET at cut line D2-D2′ in FIG. 6A;

FIG. 7 is a top view of an exemplary PFET having an independently controlled body contact region which has a reduced length to reduce parasitic capacitance;

FIG. 8A is a top view of an exemplary NFET having an independently controlled body contact region which has a reduced length to reduce parasitic capacitance;

FIG. 8B is a side view of the NFET at cut line E-E′ in FIG. 8A;

FIG. 8C is a side view of the NFET at cut line F-F′ in FIG. 8A;

FIG. 9 is a top view of an exemplary PFET having an independently controlled body contact region which has a reduced length to reduce parasitic capacitance;

FIGS. 10A-10B is a flowchart illustrating an exemplary fabrication process for fabricating a transistor having an independently controlled body contact region which has a reduced length to reduce parasitic capacitance including, but not limited to, the transistors in FIGS. 1, 2A, 3A-3E, 4, 5, 6A-6E, 7, 8A-8C, and 9; and

FIG. 11 is a block diagram of an exemplary wireless communications device that includes RF components comprising transistors wherein one or more transistors an independently controlled body contact region which has a reduced length to reduce parasitic capacitance, including, but not limited to, the transistors in FIGS. 1, 2A, 3A-3E, 4, 5, 6A-6E, 7, 8A-8C, and 9, and fabricated according to the exemplary fabrication process in FIG. 10.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

It should be understood that the terms “first,” “second,” “third,” etc., where used herein, are relative terms that may be used to distinguish between similarly named elements and are not meant to limit or imply a strict orientation and/or order unless otherwise specified. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example. For example, if a particular object that is discussed as at “top,” or “upper” or “above” another object, and such particular object is flipped 180 degrees, then such particular object would then be oriented as at “bottom,” or “lower” or “below” such other object.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

Aspects disclosed herein include a transistor having an independently controlled body contact region which has a reduced length to reduce parasitic capacitance, and related methods thereto. The transistor includes a formed from a semiconductor layer (i.e., silicon). The transistor may be a silicon-on-insulator (SOI) transistor as an example. A source region and a drain region of the transistor are formed on opposite sides of the body in the semiconductor layer by implanting or diffusing doping material of a first polarity in the semiconductor layer. The source and drain regions extend to a source end and to a drain end, respectively. A poly silicon (“poly”) region includes a gate region which is formed in an insulating layer above the body to generate an electric field in the body and control the flow of current in the body. The gate region comprises conducting material such as poly silicon (“poly”). The gate region has a gate length and a gate width extending from a first gate end in line with the first drain end to a second gate end. The poly region also includes a poly extension region which extends from the first gate end outside the perimeter of the source, drain, and gate regions. The body contact region is below the poly extension region and has a second polarity and is directly adjacent to a third side of the body. The body contact region has a reduced length approximately equal to the gate length and is coupled to a body contact independent of the source region.

In this regard, the body contact region which has a reduced length advantageously reduces the parasitic capacitance of the transistor including parasitic capacitance between the body contact region and the source and drain regions. Additionally, the independent control of the body contact region and, thus, the body bias of the transistor advantageously enables flexible tuning of characteristics of the transistor including threshold voltage. When the transistor with the body contact region having a reduced length is deployed in a low-noise amplifier (LNA), the parasitic capacitance is reduced as compared to conventional body-controlled transistors. Furthermore, when the LNA deploys the transistor with the body contact region having a reduced length as the cascode transistor, the independent body control feature can more finely tune the threshold voltage of the transistor to address headroom issues in the cascode transistor. Moreover, the transistor with the body contact region having a reduced length and the independently controlled body reduces off-state current leakage. When the transistor with the body contact region having a reduced length is deployed in a radio frequency (RF) switch, the off-state capacitance of the RF switch is reduced compared to a conventional H-gate configuration and improves the level of functionality and safety of an electrical device as measured against the standards set by the International Electrotechnical Commission (IEC).

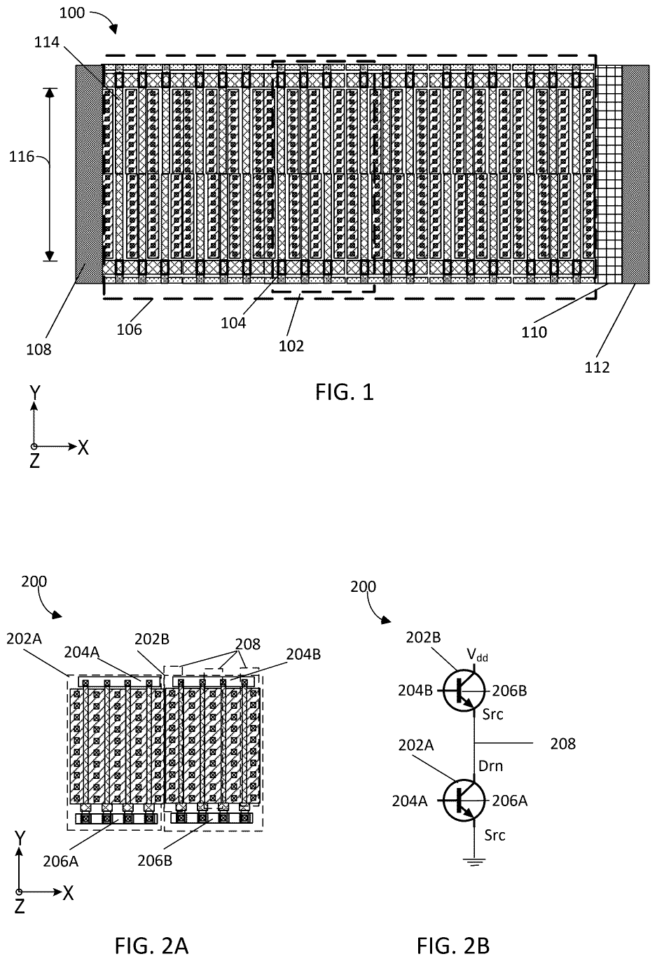

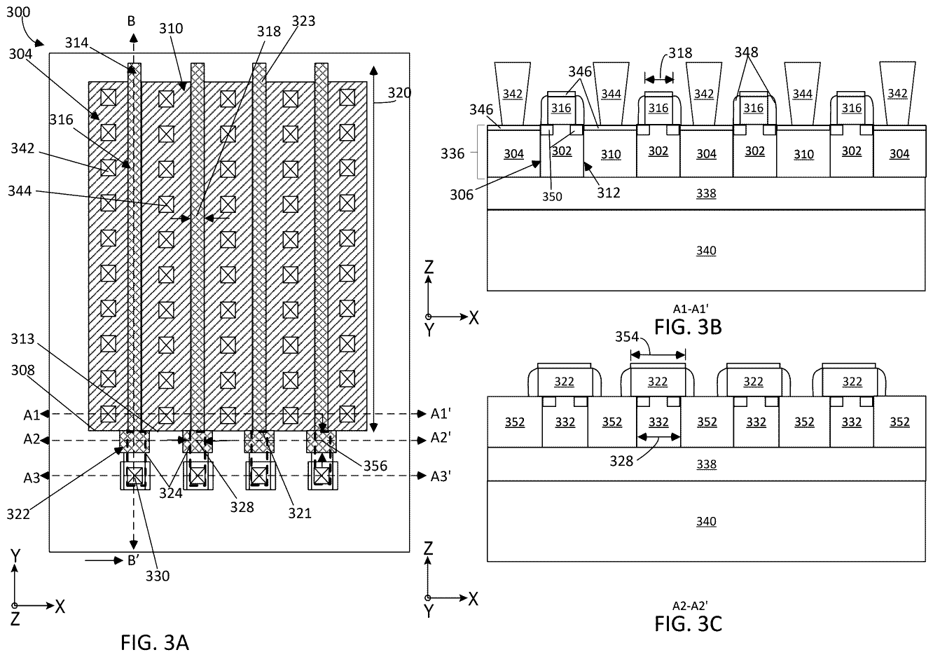

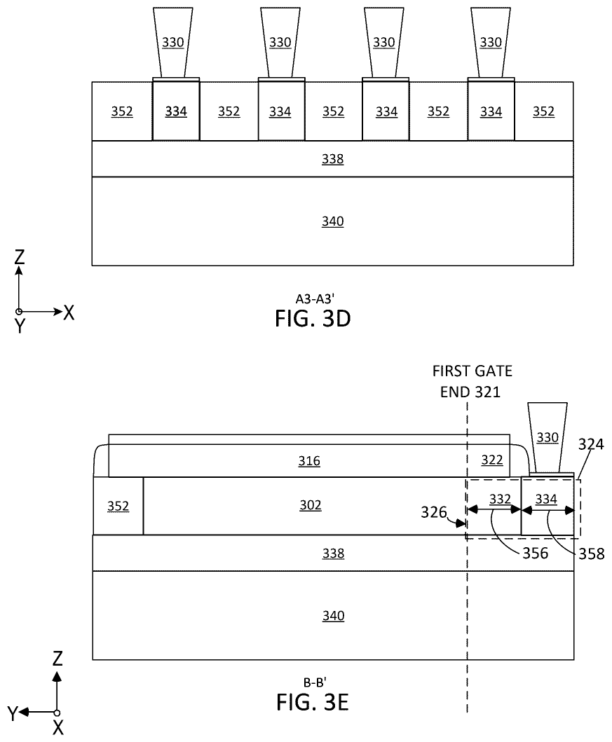

Turning to exemplary aspects, FIG. 1 is a top view of an exemplary RF switch 100 including a transistor 102 having an independently controlled body contact region 104 which has a reduced length to reduce parasitic capacitance. The RF switch 100 includes a transistor bank 106 which includes the transistor 102. The transistor bank 106 can be viewed as multiple multi-finger transistors including the transistor 102 connected in parallel which behave as a single transistor. A multi-finger transistor is a transistor with each finger being a gate with a drain abutted to one side of the gate and a source abutted to the other, opposite side of the gate. The transistor 102 will be further described in FIGS. 3A-3E, 4, 5, 6A-6E, 7, 8A-8C, and 9. The RF switch 100 includes a resistor 108 which is connected between the source and drains of the transistor bank 106. The RF switch 100 includes diodes 110 which control the signal path by directing an input RF signal to different destinations. The diodes 110 are coupled between body and gate of each of the muti-finger transistors. The RF switch 100 also includes a gate resistor 112 coupled to a gate 114 of the transistor bank 106. The gate width 116 is approximately 10 micrometers (μm). For every 5 μm of transistor gate width, a reduced length body contact region 104 is allocated for effective charge removal from the body of the transistor 102. The off-state capacitance of the RF switch 100 is reduced compared to a conventional H-gate configuration and improves the level of functionality and safety of an electrical device as measured against the standards set by the International Electrotechnical Commission (IEC).

FIGS. 3A-3E, 4, 5, 6A-6E, 7, 8A-8C, and 9 will describe embodiments of a transistor, such as the transistors 102 in the RF switch 100 and transistors 202A-202B in an LNA 200 in FIG. 2A, having an independently controlled body contact region which has a reduced length to reduce parasitic capacitance.

FIG. 2A is a top view of an exemplary LNA 200 including two transistors 202A-202B having an independently controlled body contact region (not shown) which has a reduced length to reduce parasitic capacitance. Transistor 202A is the input transistor of the LNA 200, and transistor 202B is the LNA cascode transistor. Gate contacts 204A of the transistor 202A receive RF input signals. Body contacts 206A are coupled to a body voltage bias for the transistor 202A. Gate contacts 204B of the transistor 202B is coupled to a cascode voltage (V_{casc}). Body contacts 206B are coupled to a body voltage bias for the transistor 202B. The source of the transistor 202B is coupled to the drain of the transistor 202A to create a tap 208 which is the RF output of the LNA 200. FIG. 2B is a schematic of the LNA 200 in FIG. 2A.

In this regard, the parasitic capacitance of the transistors 202A-202B is reduced as compared to conventional body-controlled transistors. Furthermore, the coupling of the body voltage bias to the body contacts 206B provides an independent body control feature to more finely tune the threshold voltage of the transistor 202B to address headroom issues in the cascode transistor 202B between V_{dd} which is coupled to the drain of the transistor 202B and a threshold voltage of the transistor 202B. Moreover, the transistors 202A-202B with the body contact region having a reduced length reduces off-state current leakage of the LNA 200.

FIGS. 3A-3E, 4, 5, 6A-6E, 7, 8A-8C, and 9 will describe embodiments of a transistor, such as the transistors 102 in the RF switch 100 in FIG. 1 and the transistors 202A-202B in the LNA 200 in FIG. 2A, having an independently controlled body contact region which has a reduced length to reduce parasitic capacitance.

FIG. 3A is a top view of an exemplary n-type field-effect transistor (FET) (NFET) 300 having an independently controlled body contact region which has a reduced length to reduce parasitic capacitance. FIG. 3A will be discussed in connection with FIGS. 3B-3E. The NFET 300 include a body region 302 (FIGS. 3B, 3E) and a drain region 304 (FIG. 3B) of a first polarity and adjacent to a first side 306 (FIG. 3B) of the body region 302 in the first, horizontal direction (X-axis direction), the drain region 304 extending in the second, horizontal direction (Y-axis direction) to a first drain end 308. The NFET 300 also includes a source region 310 of a first polarity and adjacent to a second side 312 of the body region 302 opposite the first side 306 in the first, horizontal direction (X-axis direction, see FIG. 3B). The source region 310 extends in the second, horizontal direction (Y-axis direction) to a first source end 313. The NFET 300 also includes a poly region 314. The poly region 314 includes a gate region 316 extending in the first, horizontal direction and the second, horizontal direction. The gate region 316 is adjacent to the body region 302 in a third, vertical direction (Z-axis direction). The gate region 316 has a gate length 318 extending in the first direction and a gate width 320 extending in the second direction from a first gate end 321 in line with the first drain end 308 to a second gate end 323. The poly region 314 also includes a poly extension region 322 extending in the second direction from the first gate end 321. The NFET 300 also includes a body contact region 324 (see FIG. 3E) having a second polarity and directly adjacent, in the second direction, to a third side 326 (see FIG. 3E) of the body region 302, and under the poly extension region 322, wherein the body contact region 324 has a body contact region length 328 (FIGS. 3A, 3C) in the first direction equal to the gate length 318. The term “equal” incorporates tolerance limitations of foundry rules that may not allow the poly extension region 322 to be exactly the same length as the gate length 318. The NFET 300 also includes a body contact 330 coupled to the body contact region 324 independent of the source region 310.

The body contact region 324 includes a first portion 332 (FIGS. 3C, 3E) under the poly extension region 322 and a second portion 334 (FIG. 3E) under the body contact 330.

In this embodiment, an N-type transistor is illustrated. As such, the first portion 332 is doped with a pwell material and the second portion 334 is doped P+. The first polarity is N+ and the second polarity is P+.

FIG. 3B is a side view of the NFET 300 at cut line A1-A1′ in FIG. 3A. The NFET 300 is fabricated in a semiconductor layer 336 extending in the first direction and the second direction. The semiconductor layer 336 is adjacent to or on top of an insulation layer 338 in the third, vertical direction orthogonal to the first direction and the second direction. The insulation layer 338 extends in the first direction and the second direction. The insulation layer 338 comprises buried oxide. The insulation layer 338 is on top of a silicon substrate 340. Drain contacts 342 couple to the drain region 304. Source contacts 344 couple to the source region 310. Silicide layers 346 cover the top surfaces of the drain region 304, the source region 310, and the gate region 316. Dielectric spacers 348 abut the sides in the first, horizontal direction of the gate region 316 to electrically isolate the gate region 316. Pocket implants 350 are implanted into the body region 302 and are lightly doped N+.

FIG. 3C is a side view of the NFET 300 at cut line A2-A2′ in FIG. 3A. Between the first portions 332 of the body contact region 324 in the first, horizontal direction are oxide sections 352 to electrically isolate the body contact region 324. The length of the first portion 332 of the body contact region 324 has the same length as the body contact region length 328 of the body contact region 324. Additionally, the poly extension region 322 has a poly extension length 354 in the first direction which is equal to the length of the body contact region length 328.

FIG. 3D is a side view of the NFET 300 at cut line A3-A3′ in FIG. 3A. As shown in FIG. 3D, the body contact 330 is over the second portion 334 of the body contact region 324.

FIG. 3E is a side view of the NFET 300 at cut line B-B′ in FIG. 3A. The first portion 332 of the body contact region 324 has a width 356 in the second direction (see also FIG. 3A). The second portion 334 of the body contact region 324 has a width 358 in the second direction. The width 356 is equal to the width 358. Together width 356 and width 358 are at least equal to or greater than the gate length 318 and less than twice the gate length 328.

The term “equal” incorporates tolerance limitations of foundry rules that may not allow lengths of the poly extension region 322, the body contact region 324, and the gate region 316 to be exactly the same length.

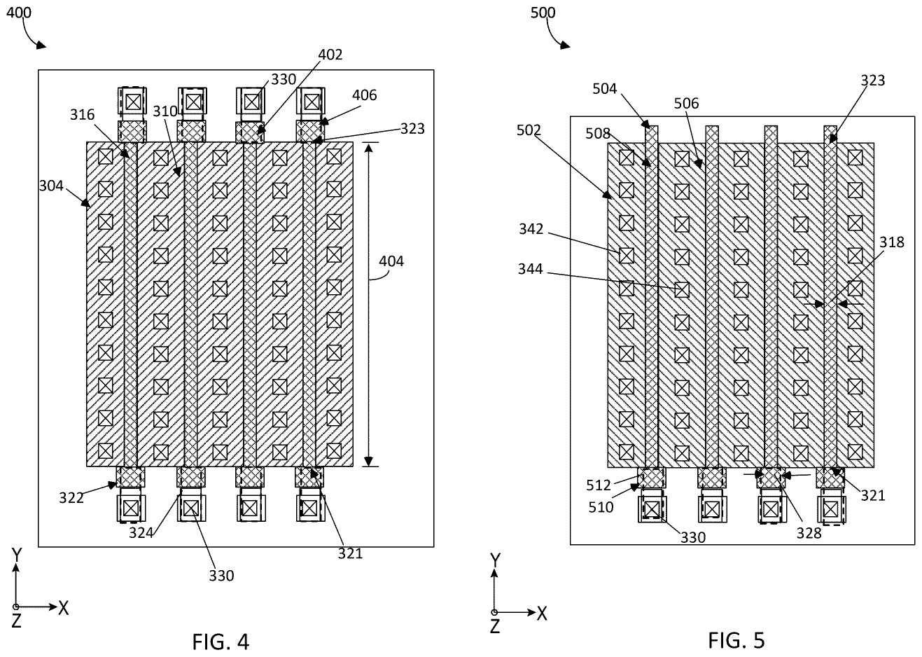

FIG. 4 is a top view of an exemplary NFET 400 having an independently controlled body contact region 402 which has a reduced length to reduce parasitic capacitance wherein a gate width 404 of the NFET 400 is greater than or equal to 4 μm. Common elements between the NFET 400 in FIG. 4 and the NFET 300 in FIGS. 3A-3E are shown with common element numbers. The gate width 404 is defined between the first gate end 321 and the second gate end 323. An additional poly extension region 406 and the body contact region 402 which is under the poly extension region 406 are included in the NFET 400 in order to achieve lower parasitic capacitance and continue to drain any build up of electron hole pairs in the body during operation.

FIG. 5 is a top view of an exemplary p-type FET (PFET) 500 having an independently controlled body contact region which has a reduced length to reduce parasitic capacitance. Common elements between the PFET 500 in FIG. 5 and the NFET 300 in FIGS. 3A-3E are shown with common element numbers. The PFET 500 comprises a drain region 502, a poly region 504, and a source region 506. The poly region 504 includes a gate region 508 between the drain region 502 and the source region 506 and a poly extension region 510. A body region (not shown) is under the gate region 508 and between the drain region 502 and the source region 506. The body region comprises an nwell material. A body contact region 512 is below, in the third direction (Z-axis direction), the poly extension region 510 and the body contact 330. The first portion (not shown) of the body contact region 512 which is under the poly extension region 510 comprises an nwell material, and the second portion (not shown) of the body contact region 512 which is under the body contact 330 is doped N+. The first polarity of the drain region 502 and the source region 506 is P+.

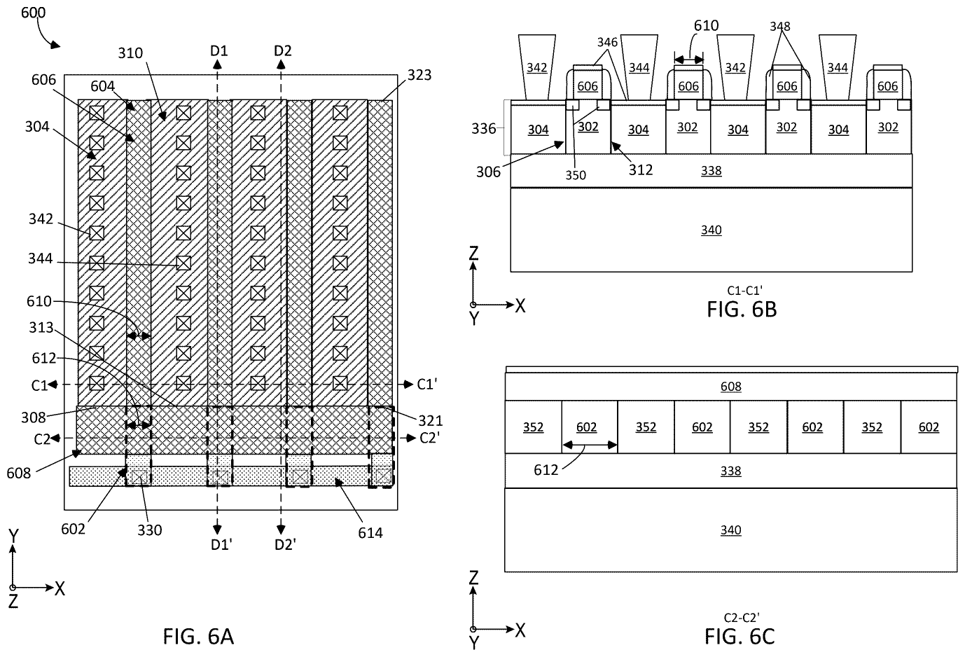

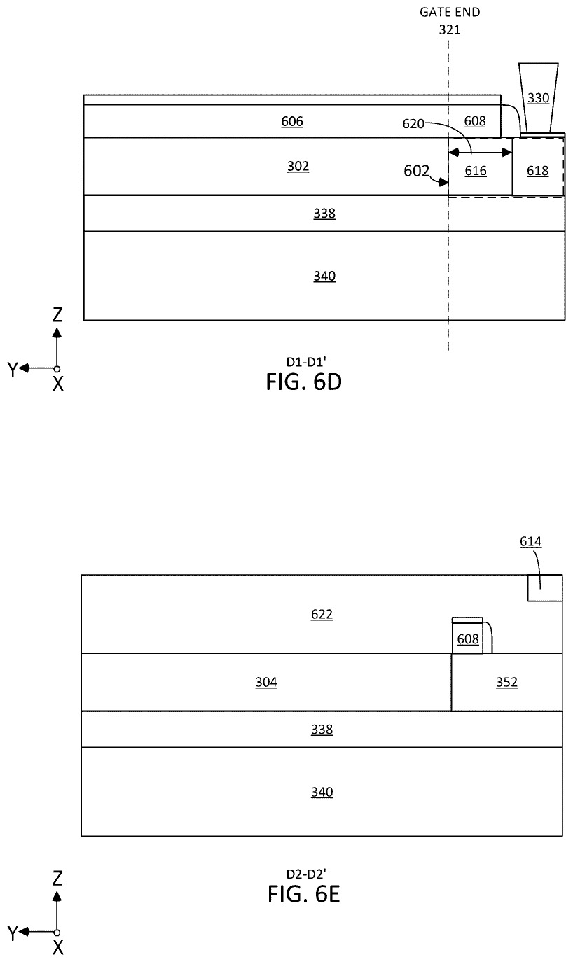

FIG. 6A is a top view of an exemplary NFET 600 having an independently controlled body contact region 602 which has a reduced length to reduce parasitic capacitance. Common elements between the NFET 600 in FIGS. 6A-6E and the NFET 300 in FIGS. 3A-3E are shown with common element numbers. FIG. 6A will be discussed in connection with FIGS. 6B-6E. The NFET 600 includes a poly region 604. The poly region 604 includes a gate region 606 and a poly extension region 608. The gate region 606 has a gate length 610 and a body region 302 under the gate region 606. The body contact region 602 is under the poly extension region 608. The body contact region 602 has a body contact region length 612 which is equal to the gate length 610. The poly extension region 608 extends in the first direction (X-axis direction) at least between the first drain end 308 and the first source end 313 which, in this example, is 0.15 μm. The body contacts 330 are coupled to a metal trace 614 and are coupled to the body contact region 602 independent of the source and drain regions 310, 304.

FIG. 6B is a side view of the NFET 600 at cut line C1-C1′ in FIG. 6A.

FIG. 6C is a side view of the NFET 600 at cut line C2-C2′ in FIG. 6A.

FIG. 6D is a side view of the NFET 600 at cut line D1-D1′ in FIG. 6A. The body contact region 602 includes a first portion 616 under the poly extension region 608 and a second portion 618 under the body contact 330. The first portion 616 is a pwell material and the second portion is doped P+. The first portion 616 has a width 620 which is no larger than twice the minimum gate length allowed by the technology node utilized when manufacturing NFET 600, such as gate length 610.

FIG. 6E is a side view of the NFET 600 at cut line D2-D2′ in FIG. 6A. An inter-dielectric layer 622 is on top of the drain region 304 and the source region 310 (not shown).

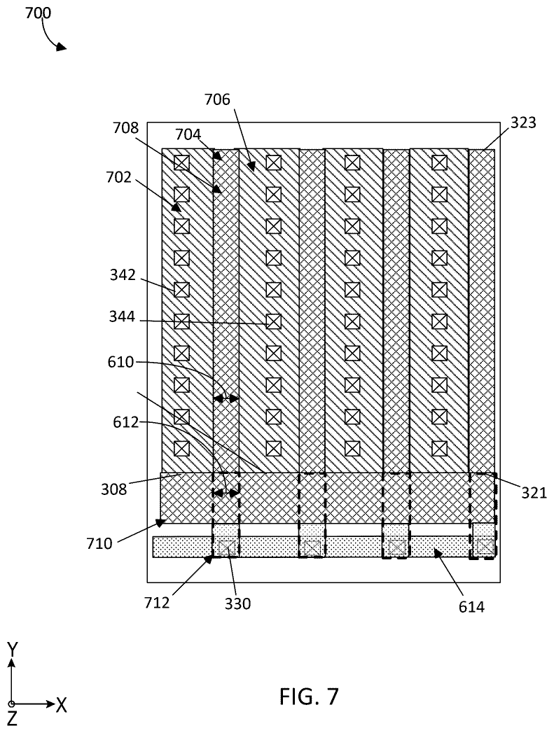

FIG. 7 is a top view of an exemplary PFET 700 having an independently controlled body contact region which has a reduced length to reduce parasitic capacitance. Common elements between the PFET 700 in FIG. 7 and the NFET 600 in FIGS. 6A-6E are shown with common element numbers. The PFET 700 comprises a drain region 702, a poly region 704, and a source region 706. The poly region 704 includes a gate region 708 between the drain region 702 and the source region 706 and a poly extension region 710. A body region (not shown) is under the gate region 708 and between the drain region 702 and the source region 706. The body region comprises an nwell material. A body contact region 712 is below, in the third direction (Z-axis direction), the poly extension region 710 and the body contact 330. The first portion (not shown) of the body contact region 712 which is under the poly extension region 710 comprises an nwell material, and the second portion (not shown) of the body contact region 712 which is under the body contact 330 is doped N+. The first polarity of the drain region 702 and the source region 706 is P+.

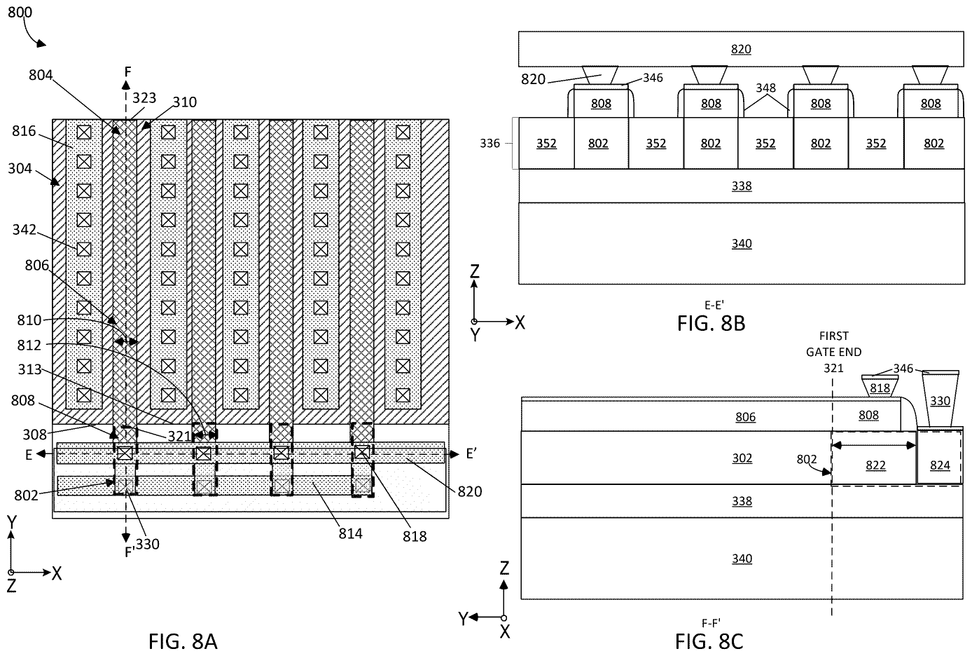

FIG. 8A is a top view of an exemplary NFET 800 having an independently controlled body contact region 802 which has a reduced length to reduce parasitic capacitance. Common elements between the NFET 800 in FIGS. 8A-8E and the NFET 300 in FIGS. 3A-3E are shown with common element numbers. FIG. 8A will be discussed in connection with FIGS. 8B-8C. The NFET 800 includes a poly region 804. The poly region 804 includes a gate region 806 and a poly extension region 808. The gate region 806 has a gate length 810 and a body region 302 under the gate region 806. The body contact region 802 is under the poly extension region 808. The body contact region 802 has a body contact region length 812 which is equal to the gate length 810. The poly extension region 808 extends from the first gate end 321 just past the body contact 330. The body contact 330 is coupled to a metal trace 814 and is coupled to the body contact region 802 independent of the source and drain regions 310, 304. The drain contacts 342 are coupled via a metal trace 816. A gate contact 818 is above the body contact region 802 in the vertical direction (Z-axis direction) and couples to the body contact region 802. A metal trace 820 couples to the gate contact(s) 818.

FIG. 8B is a side view of the NFET 800 at cut line E-E′ in FIG. 8A. No new elements are added. FIG. 8B merely shows another perspective of NFET 800 for clarity purposes.

FIG. 8C is a side view of the NFET 800 at cut line F-F′ in FIG. 8A. The body contact region 802 includes a first portion 822 under the poly extension region 808 and a second portion 824 under the body contact 330. The first portion 822 comprises a pwell material. The second portion 824 is doped P+.

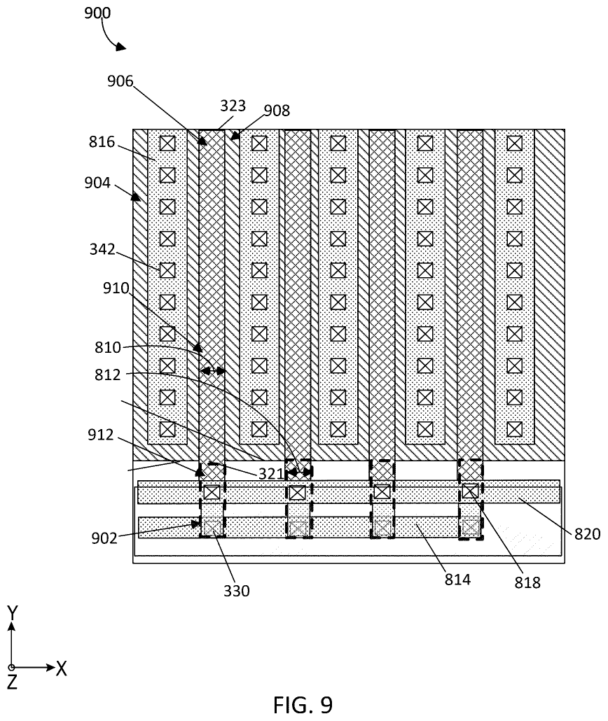

FIG. 9 is a top view of an exemplary PFET 900 having an independently controlled body contact region 902 which has a reduced length to reduce parasitic capacitance. Common elements between the PFET 900 in FIG. 9 and the NFET 800 in FIGS. 8A-8C are shown with common element numbers. The PFET 900 comprises a drain region 904, a poly region 906, and a source region 908. The poly region 906 includes a gate region 910 between the drain region 904 and the source region 908 and a poly extension region 912. A body region (not shown) is under the gate region 910 and between the drain region 904 and the source region 908. The body region comprises an nwell material. The body contact region 902 is below, in the third direction (Z-axis direction), the poly extension region 912 and the body contact 330. The first portion (not shown) of the body contact region 902 which is under the poly extension region 912 comprises an nwell material, and the second portion (not shown) of the body contact region 902 which is under the body contact 330 is doped N+. The first polarity of the drain region 904 and the source region 908 is P+.

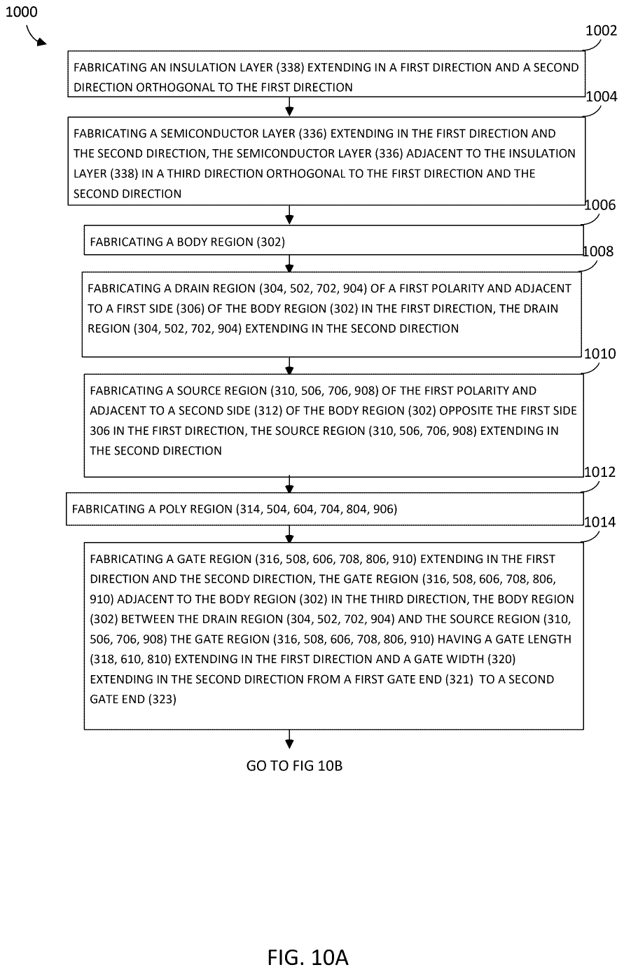

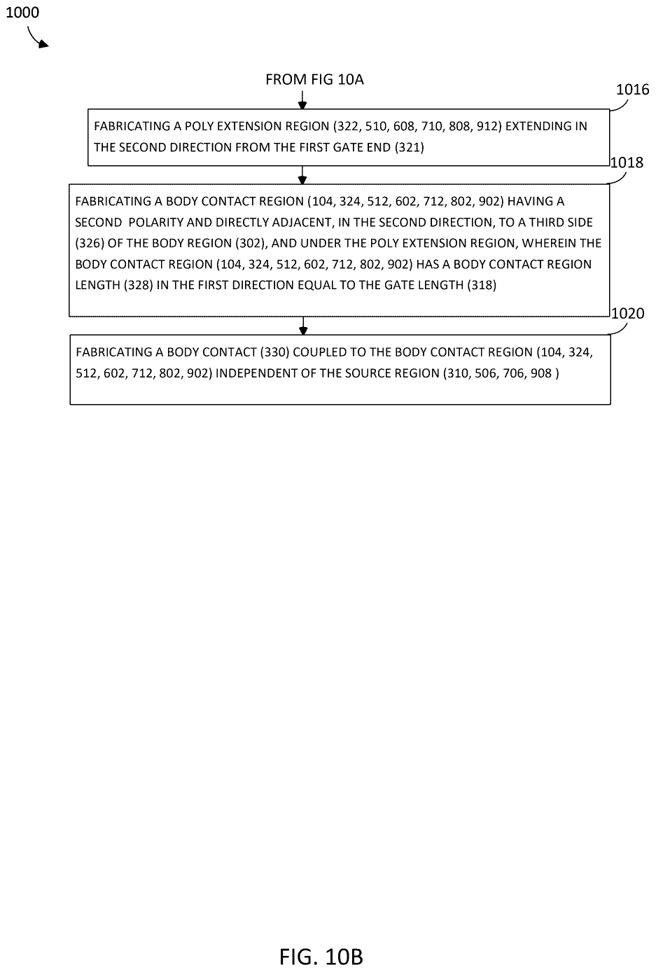

FIGS. 10A-10B is a flowchart illustrating an exemplary fabrication process 1000 for fabricating a transistor having an independently controlled body contact region which has a reduced length to reduce parasitic capacitance including, but not limited to, the transistors 106, 202A-202B, 300, 400, 500, 600, 700, 800, 900 in FIGS. 1, 2A, 3A-3E, 4, 5, 6A-6E, 7, 8A-8C, and 9. In this regard, a first exemplary step in the fabrication process 1000 for fabricating a transistor having an independently controlled body contact region which has a reduced length to reduce parasitic capacitance can include fabricating an insulation layer 338 extending in a first direction and a second direction orthogonal to the first direction (block 1002 in FIG. 10A). The next step in the fabrication process 1000 can include fabricating a semiconductor layer 336 extending in the first direction and the second direction, the semiconductor layer 336 adjacent to the insulation layer 338 in a third direction orthogonal to the first direction and the second direction (block 1004 in FIG. 10A). In this regard, fabricating the semiconductor layer 336 can include fabricating a body region 302 (block 1006 in FIG. 10A). The next step in the fabrication of the semiconductor layer 336 in the fabrication process 1000 can include fabricating a drain region 304, 502, 702, and 904 of a first polarity and adjacent to a first side 306 of the body region 302 in the first direction, the drain region 304, 502, 702, and 904 extending in the second direction (block 1008 in FIG. 10A). The next step in the fabrication of the semiconductor layer 336 in the fabrication process 1000 can include fabricating a source region 310, 506, 706, 908 of the first polarity and adjacent to a second side 312 of the body region 302 opposite the first side 306 in the first direction, the source region 310, 506, 706, 908 extending in the second direction (block 1010 in FIG. 10A). The next step in the fabrication process 1000 can include fabricating a poly region 314, 504, 604, 704, 804, 906 (block 1012 in FIG. 10A). In this regard, fabricating the poly region 314, 504, 604, 704, 804, 906 can include fabricating a gate region 316, 508, 606, 708, 806, 910 extending in the first direction and the second direction, the gate region 316, 508, 606, 708, 806, 910 adjacent to the body region 302 in the third direction, the body region 302 between the drain region 304, 502, 702, 904 and the source region 310, 506, 706, 908, the gate region 316, 508, 606, 708, 806, 910 having a gate length 318, 610, 810 extending in the first direction and a gate width 320 extending in the second direction from a first gate end 321 to a second gate end 323 (block 1014 in FIG. 10A). The next step in fabricating the poly region 314, 504, 604, 704, 804, 906 can include fabricating a poly extension region 322, 510, 608, 710, 808, 912 extending in the second direction from the first gate end 321 (block 1016 in FIG. 10B). The next step in the fabrication process 1000 can include fabricating a body contact region 104, 324, 512, 602, 712, 802, 902 having a second polarity and directly adjacent, in the second direction, to a third side 326 of the body region 302, and under the poly extension region, wherein the body contact region 104, 324, 512, 602, 712, 802, 902 has a body contact region length 328 in the first direction equal to the gate length 318 (block 1018 in FIG. 10B). The next step in the fabrication process 1000 can include fabricating a body contact 330 coupled to the body contact region 104, 324, 512, 602, 712, 802, 902 independent of the source region 310, 506, 706, 908 (block 1020 in FIG. 10B).

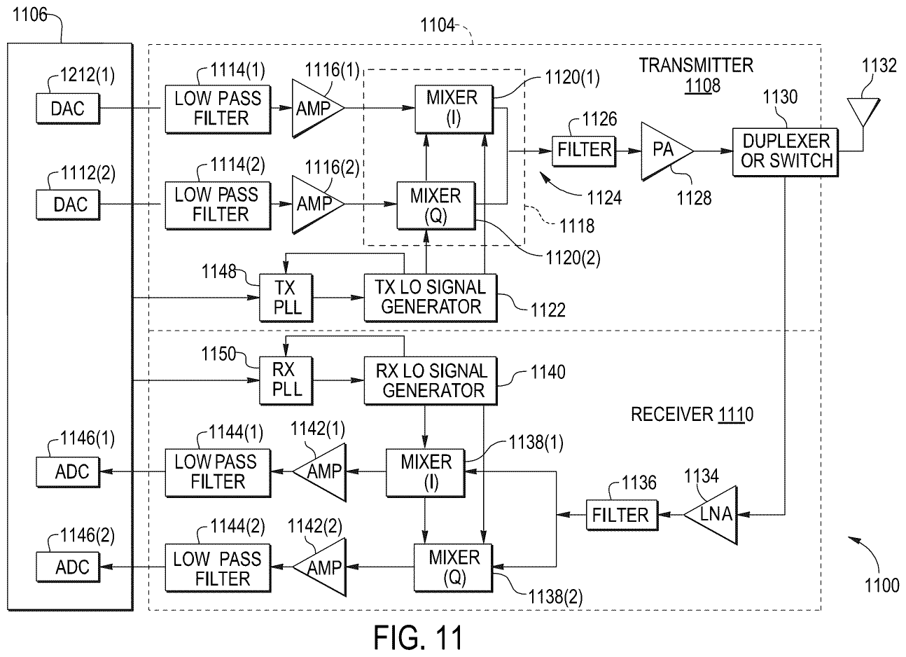

FIG. 11 is a block diagram of an exemplary wireless communications device that includes RF components comprising transistors wherein one or more transistors an independently controlled body contact region which has a reduced length to reduce parasitic capacitance, including, but not limited to, the transistors in FIGS. 1, 2A, 3A-3E, 4, 5, 6A-6E, 7, 8A-8C, and 9, and fabricated according to the exemplary fabrication process in FIG. 10.

As shown in FIG. 11, the wireless communications device 1100 includes a transceiver 1104 and a data processor 1106. The data processor 1106 may include a memory to store data and program codes. The transceiver 1104 includes a transmitter 1108 and a receiver 1110 that support bi-directional communications. In general, the wireless communications device 1100 may include any number of transmitters 1108 and/or receivers 1110 for any number of communication systems and frequency bands. All or a portion of the transceiver 1104 may be implemented on one or more analog ICs, RF ICs (RFICs), mixed-signal ICs, etc.

The transmitter 1108 or the receiver 1110 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 1110. In the direct-conversion architecture, a signal is frequency-converted between RF and baseband in one stage. The super-heterodyne and direct-conversion architectures may use different circuit blocks and/or have different requirements. In the wireless communications device 1100 in FIG. 11, the transmitter 1108 and the receiver 1110 are implemented with the direct-conversion architecture.

In the transmit path, the data processor 1106 processes data to be transmitted and provides I and Q analog output signals to the transmitter 1108. In the exemplary wireless communications device 1100, the data processor 1106 includes digital-to-analog converters (DACs) 1112(1), 1112(2) for converting digital signals generated by the data processor 1106 into the I and Q analog output signals (e.g., I and Q output currents) for further processing.

Within the transmitter 1108, lowpass filters 1114(1), 1114(2) filter the I and Q analog output signals, respectively, to remove undesired signals caused by the prior digital-to-analog conversion. Amplifiers (AMPs) 1116(1), 1116(2) amplify the signals from the lowpass filters 1114(1), 1114(2), respectively, and provide I and Q baseband signals. An upconverter 1118 upconverts the I and Q baseband signals with I and Q transmit (TX) local oscillator (LO) signals through mixers 1120(1), 1120(2) from a TX LO signal generator 1122 to provide an upconverted signal 1124. A filter 1126 filters the upconverted signal 1124 to remove undesired signals caused by the frequency up-conversion as well as noise in a receive frequency band. A power amplifier (PA) 1128 amplifies the upconverted signal 1124 from the filter 1126 to obtain the desired output power level and provides a transmit RF signal. The transmit RF signal is routed through a duplexer or switch 1130 and transmitted via an antenna 1132.

In the receive path, the antenna 1132 receives signals transmitted by base stations and provides a received RF signal, which is routed through the duplexer or switch 1130 and provided to a low noise amplifier (LNA) 1134. The duplexer or switch 1130 is designed to operate with a specific receive (RX)-to-TX duplexer frequency separation, such that RX signals are isolated from TX signals. The received RF signal is amplified by the LNA 1134 and filtered by a filter 1136 to obtain a desired RF input signal. Down-conversion mixers 1138(1), 1138(2) mix the output of the filter 1136 with I and Q RX LO signals (i.e., LO_I and LO_Q) from an RX LO signal generator 1140 to generate I and Q baseband signals. The I and Q baseband signals are amplified by AMPs 1142(1), 1142(2) and further filtered by lowpass filters 1144(1), 1144(2) to obtain I and Q analog input signals, which are provided to the data processor 1106. In this example, the data processor 1106 includes analog-to-digital converters (ADCs) 1146(1), 1146(2) for converting the analog input signals into digital signals to be further processed by the data processor 1106.

In the wireless communications device 1100 of FIG. 11, the TX LO signal generator 1122 generates the I and Q TX LO signals used for frequency up-conversion, while the RX LO signal generator 1140 generates the I and Q RX LO signals used for frequency down-conversion. Each LO signal is a periodic signal with a particular fundamental frequency. A TX phase-locked loop (PLL) circuit 1148 receives timing information from the data processor 1106 and generates a control signal used to adjust the frequency and/or phase of the TX LO signals from the TX LO signal generator 1122. Similarly, an RX PLL circuit 1150 receives timing information from the data processor 1106 and generates a control signal used to adjust the frequency and/or phase of the RX LO signals from the RX LO signal generator 1140.

A semiconductor die including transistors wherein one or more transistors having an independently controlled body contact region which has a reduced length to reduce parasitic capacitance as disclosed in aspects described herein may be provided in or integrated into an IC and deployed in any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. An electronic device, comprising:
   an insulation layer extending in a first direction and a second direction orthogonal to the first direction; and
   a semiconductor layer extending in the first direction and the second direction, the semiconductor layer adjacent to the insulation layer in a third direction orthogonal to the first direction and the second direction, the semiconductor layer comprising:
      a transistor, comprising:
         a body region;
         a drain region of a first polarity and adjacent to a first side of the body region in the first direction, the drain region extending in the second direction;
         a source region of the first polarity and adjacent to a second side of the body region opposite the first side in the first direction;
         a poly region, comprising:
         a gate region extending in the first direction and the second direction, the gate region adjacent to the body region in the third direction, the body region between the drain region and the source region, the gate region having a gate length extending in the first direction and a gate width extending in the second direction from a first gate end to a second gate end; and
         a poly extension region extending in the second direction from the first gate end;
         a body contact region having a second polarity and directly adjacent, in the second direction, to a third side of the body region, and under the poly extension region, wherein the body contact region has a body contact region length in the first direction equal to the gate length; and
         a body contact coupled to the body contact region independent of the source region.
2. The electronic device of clause 1, further comprising:
   a radio frequency (RF) switch, comprising:
      the transistor;
      a resistor coupled between the source region and the drain region;
      a gate resistor coupled to the gate region; and
      diodes coupled between the body region and the gate region.
3. The electronic device of clause 1, further comprising:
   a low noise amplifier, comprising:
      the transistor, wherein the gate region is coupled to a radio frequency (RF) input, the source region is coupled to ground, and the drain region is coupled to an RF output, the body contact coupled to a first body voltage bias; and
      a second transistor, comprising:
         a second source region coupled to the RF output;
         a second drain region coupled to Vdd;
         a second body contact coupled to a second body voltage bias; and
         a second gate coupled to Vcasc.
4. The electronic device of any of clauses 1-3, wherein the poly extension region extends in the first direction and has a poly extension length in the first direction equal to the gate length.
5. The electronic device of any of clauses 1-3, wherein:
   the drain region extends in the second direction to a first drain end;
   the source region extends in the second direction to a first source end; and
   the poly extension region extends in the first direction at least between the first drain end and the first source end.
6. The electronic device of any of clauses 1-5, further comprising:
   a gate contact coupled to the body contact region.
7. The electronic device of any of clauses 1-6, wherein the body contact region has a first portion, the first portion having a first portion width that is no larger than twice the gate length.
8. The electronic device of any of clauses 1-7, wherein:
   the first polarity is n+and the second polarity is p+.
9. The electronic device of any of clauses 1-7, wherein:
   the first polarity is p+and the second polarity is n+.
10. The electronic device of any of clauses 1-8, wherein the gate width is greater than or equal to four micrometers (4 μm), the transistor further comprising:
   the drain region extending in the second direction to a second drain end;
   the source region extending in the second direction to a second source end;
   a second poly extension region extending in the second direction from the second gate end;
   a second body contact region directly adjacent to a fourth side of the body region, and under the second poly extension region, wherein the second body contact region has a second body contact region length in the first direction equal to the gate length; and
   a second body contact coupled to the second body contact region independent of the source region.
11. A method for fabricating an electronic device to reduce parasitic capacitance, comprising:
   fabricating an insulation layer extending in a first direction and a second direction orthogonal to the first direction; and
   fabricating a semiconductor layer extending in the first direction and the second direction, the semiconductor layer adjacent to the insulation layer in a third direction orthogonal to the first direction and the second direction, wherein fabricating the semiconductor layer comprises:
      fabricating a body region;
      fabricating a drain region of a first polarity and adjacent to a first side of the body region in the first direction, the drain region extending in the second direction; and
      fabricating a source region of the first polarity and adjacent to a second side of the body region opposite the first side in the first direction, the source region extending in the second direction;
   fabricating a poly region, comprising:
      fabricating a gate region extending in the first direction and the second direction, the gate region adjacent to the body region in the third direction, the body region between the drain region and the source region, the gate region having a gate length extending in the first direction and a gate width extending in the second direction from a first gate end to a second gate end; and
      fabricating a poly extension region extending in the second direction from the first gate end;
   fabricating a body contact region having a second polarity and directly adjacent, in the second direction, to a third side of the body region, and under the poly extension region, wherein the body contact region has a body contact region length in the first direction equal to the gate length; and
   fabricating a body contact coupled to the body contact region independent of the source region.
12. The method of clause 11, wherein the poly extension region extends in the first direction and has a poly extension length in the first direction equal to the gate length.
13. The method of clause 11 or 12, wherein:
   the drain region extends in the second direction to a first drain end;
   the source region extends in the second direction to a first source end; and
   the poly extension region extends in the first direction at least between the first drain end and the first source end.
14. The method of any of clauses 11-13, further comprising:
   fabricating a gate contact coupled to the body contact region.
15. The method of any of clauses 11-14, wherein the body contact region has a first portion, the first portion having a first portion width that is no larger than twice the gate length.
16. The method of any of clauses 11-15, wherein:
   the first polarity is n+and the second polarity is p+.
17. The method of any of clauses 11-15, wherein:
   the first polarity is p+and the second polarity is n+.
18. An n-type field-effect transistor (FET) (NFET), comprising:
   a semiconductor layer extending in a first direction and a second direction orthogonal to the first direction, the semiconductor layer comprising:
      a body region;
      an n-type drain region adjacent to a first side of the body region in the first direction, the n-type drain region extending in the second direction;
      an n-type source region adjacent to a second side of the body region opposite the first side in the first direction, the n-type source region extending in the second direction;
      a poly region, comprising:
         a gate region extending in the first direction and the second direction, the gate region above the body region, the body region between the n-type drain region and the n-type source region, the gate region having a gate length extending in the first direction and a gate width extending in the second direction from a first gate end to a second gate end; and
         a poly extension region extending in the second direction from the first gate end;
   a p-type body contact region directly adjacent, in the second direction, to a third side of the body region, and under the poly extension region, wherein the p-type body contact region has a body contact region length in the first direction equal to the gate length; and
   a body contact coupled to the p-type body contact region independent of the n-type source region.
19. The NFET of clause 18, wherein:
   the n-type drain region extends in the second direction to a first drain end;
   the n-type source region extends in the second direction to a first source end; and
   the poly extension region extends in the first direction at least between the first drain end and the first source end.
20. The NFET of clause 18, further comprising:
   a gate contact coupled to the p-type body contact region.

What is claimed is:

1. An electronic device, comprising:
an insulation layer extending in a first direction and a second direction orthogonal to the first direction; and
a semiconductor layer extending in the first direction and the second direction, the semiconductor layer adjacent to the insulation layer in a third direction orthogonal to the first direction and the second direction, the semiconductor layer comprising:
a transistor, comprising:
a body region;
a drain region of a first polarity and adjacent to a first side of the body region in the first direction, the drain region extending in the second direction;
a source region of the first polarity and adjacent to a second side of the body region opposite the first side in the first direction;
a poly region, comprising:
a gate region extending in the first direction and the second direction, the gate region adjacent to the body region in the third direction, the body region between the drain region and the source region, the gate region having a gate length extending in the first direction and a gate width extending in the second direction from a first gate end to a second gate end; and
a poly extension region extending in the second direction from the first gate end;
a body contact region having a second polarity and directly adjacent, in the second direction, to a third side of the body region, and under the poly extension region, wherein the body contact region has a body contact region length in the first direction equal to the gate length; and
a body contact coupled to the body contact region independent of the source region.

2. The electronic device of claim 1, further comprising:
a radio frequency (RF) switch, comprising:
the transistor;
a resistor coupled between the source region and the drain region;
a gate resistor coupled to the gate region; and
diodes coupled between the body region and the gate region.

3. The electronic device of claim 1, further comprising:
a low noise amplifier, comprising:
the transistor, wherein the gate region is coupled to a radio frequency (RF) input, the source region is coupled to ground, and the drain region is coupled to an RF output, the body contact coupled to a first body voltage bias; and
a second transistor, comprising:
a second source region coupled to the RF output;
a second drain region coupled to Vdd;
a second body contact coupled to a second body voltage bias; and
a second gate coupled to Vcasc.

4. The electronic device of claim 1, wherein the poly extension region extends in the first direction and has a poly extension length in the first direction equal to the gate length.

5. The electronic device of claim 1, wherein:
the drain region extends in the second direction to a first drain end;
the source region extends in the second direction to a first source end; and
the poly extension region extends in the first direction at least between the first drain end and the first source end.

6. The electronic device of claim 1, further comprising:
a gate contact coupled to the body contact region.

7. The electronic device of claim 1, wherein the body contact region has a first portion, the first portion having a first portion width that is no larger than twice the gate length.

8. The electronic device of claim 1, wherein:
the first polarity is n+ and the second polarity is p+.

9. The electronic device of claim 1, wherein:
the first polarity is p+ and the second polarity is n+.

10. The electronic device of claim 1, wherein the gate width is greater than or equal to four micrometers (4 μm), the transistor further comprising:
the drain region extending in the second direction to a second drain end;
the source region extending in the second direction to a second source end;
a second poly extension region extending in the second direction from the second gate end;
a second body contact region directly adjacent to a fourth side of the body region, and under the second poly extension region, wherein the second body contact region has a second body contact region length in the first direction equal to the gate length; and
a second body contact coupled to the second body contact region independent of the source region.

11. A method for fabricating an electronic device to reduce parasitic capacitance, comprising:
fabricating an insulation layer extending in a first direction and a second direction orthogonal to the first direction; and
fabricating a semiconductor layer extending in the first direction and the second direction, the semiconductor layer adjacent to the insulation layer in a third direction orthogonal to the first direction and the second direction, wherein fabricating the semiconductor layer comprises:
fabricating a body region;
fabricating a drain region of a first polarity and adjacent to a first side of the body region in the first direction, the drain region extending in the second direction; and
fabricating a source region of the first polarity and adjacent to a second side of the body region opposite the first side in the first direction, the source region extending in the second direction;
fabricating a poly region, comprising:
fabricating a gate region extending in the first direction and the second direction, the gate region adjacent to the body region in the third direction, the body region between the drain region and the source region, the gate region having a gate length extending in the first direction and a gate width extending in the second direction from a first gate end to a second gate end; and
fabricating a poly extension region extending in the second direction from the first gate end;
fabricating a body contact region having a second polarity and directly adjacent, in the second direction, to a third side of the body region, and under the poly extension region, wherein the body contact region has a body contact region length in the first direction equal to the gate length; and
fabricating a body contact coupled to the body contact region independent of the source region.

12. The method of claim 11, wherein the poly extension region extends in the first direction and has a poly extension length in the first direction equal to the gate length.

13. The method of claim 11, wherein:
the drain region extends in the second direction to a first drain end;
the source region extends in the second direction to a first source end; and
the poly extension region extends in the first direction at least between the first drain end and the first source end.

14. The method of claim 11, further comprising:
fabricating a gate contact coupled to the body contact region.

15. The method of claim 11, wherein the body contact region has a first portion, the first portion having a first portion width that is no larger than twice the gate length.

16. The method of claim 11, wherein:
the first polarity is n+ and the second polarity is p+.

17. The method of claim 11, wherein:
the first polarity is p+ and the second polarity is n+.

18. An n-type field-effect transistor (FET) (NFET), comprising:
a semiconductor layer extending in a first direction and a second direction orthogonal to the first direction, the semiconductor layer comprising:
a body region;
an n-type drain region adjacent to a first side of the body region in the first direction, the n-type drain region extending in the second direction;
an n-type source region adjacent to a second side of the body region opposite the first side in the first direction, the n-type source region extending in the second direction;
a poly region, comprising:
a gate region extending in the first direction and the second direction, the gate region above the body region, the body region between the n-type drain region and the n-type source region, the gate region having a gate length extending in the first direction and a gate width extending in the second direction from a first gate end to a second gate end; and
a poly extension region extending in the second direction from the first gate end;
a p-type body contact region directly adjacent, in the second direction, to a third side of the body region, and under the poly extension region, wherein the p-type body contact region has a body contact region length in the first direction equal to the gate length; and
a body contact coupled to the p-type body contact region independent of the n-type source region.

19. The NFET of claim 18, wherein:
the n-type drain region extends in the second direction to a first drain end;
the n-type source region extends in the second direction to a first source end; and
the poly extension region extends in the first direction at least between the first drain end and the first source end.

20. The NFET of claim 18, further comprising:
a gate contact coupled to the p-type body contact region.
